(19) United States
(12) Patent Application Publication
(10) Pub. No.: US 2025/0140525 A1
(43) Pub. Date: May 1, 2025

(54) PLASMA TREATMENT METHOD AND PLASMA TREATMENT DEVICE

(71) Applicant: Tokyo Electron Limited, Tokyo (JP)

(72) Inventors: Masamichi NOMURA, Nirasaki City (JP); Yusuke SAITO, Nirasaki City (JP); Keisuke HIRAIDE, Nirasaki City (JP)

(21) Appl. No.: 19/006,494

(22) Filed: Dec. 31, 2024

Related U.S. Application Data
(63) Continuation of application No. PCT/JP2023/030581, filed on Aug. 24, 2023.

(30) Foreign Application Priority Data
Sep. 1, 2022 (JP) 2022-139061

(51) Int. Cl. H01J 37/32

(52) U.S. Cl. CPC H01J 37/32174; H01J 37/3211; H01J 2237/334

(57) ABSTRACT

A plasma processing method using a plasma processing apparatus includes: acquiring a parameter including a first initial power value, an initial power application time, and an output suppress ratio; acquiring a processing recipe including a recipe set power value as a second initial power value; determining initial input power to an antenna for plasma excitation from either the first initial power value or the second initial power value, wherein when the first initial power value is determined as the initial input power, the method further includes: supplying the determined initial input power to the antenna for plasma excitation for at least a time duration equal to or greater than the initial power application time; and increasing an output of radio frequency power supplied to the antenna for plasma excitation stepwise from the initial input power to the recipe set power value.

### CROSS-REFERENCE TO RELATED APPLICATION

The application is a Bypass Continuation Application of PCT International Application No. PCT/JP2023/030581, filed on Aug. 24, 2023 and designating the United States, the international application being based upon and claiming the benefit of priority from Japanese Patent Application No. 2022-139061, filed on Sep. 1, 2022, the entire content of which is incorporated herein by reference.

### TECHNICAL FIELD

The present disclosure relates to a plasma processing method and a plasma processing apparatus.

### BACKGROUND

Patent Document 1 discloses a plasma processing apparatus for facilitating plasma ignition and reducing an ignition time, which includes at least one of a matcher control means, a magnetic field setting means, or a pressure control means. The apparatus disclosed in Patent Document 1 aims to shorten a time from feeding radio frequency power to igniting plasma (ignition delay time) by the means described above.

In addition, Patent Document 2 discloses a method of detecting a state of an inductively coupled plasma source. The method disclosed in Patent Document 2 aims to accurately detect transition of the plasma source from capacitively coupled plasma to inductively coupled plasma.

### PRIOR ART DOCUMENTS

### Patent Documents

Patent Document 1: Japanese Patent Laid-open Publication No. 2008-060304
Patent Document 2: Japanese Patent Laid-open Publication No. 2021-157946

### SUMMARY

According to an aspect of the present disclosure, a plasma processing method using a plasma processing apparatus includes: acquiring a parameter including a first initial power value, an initial power application time, and an output suppress ratio; acquiring a processing recipe including a recipe set power value as a second initial power value; and determining initial input power to an antenna for plasma excitation from either the first initial power value or the second initial power value, wherein when the first initial power value is determined as the initial input power, the method further includes supplying the determined initial input power to the antenna for plasma excitation for at least a time duration equal to or greater than the initial power application time; and increasing an output of radio frequency power supplied to the antenna for plasma excitation stepwise from the initial input power to the recipe set power value.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a graph illustrating a temporal change in a Vpp value during plasma generation.

FIG. 2 is a plan view illustrating an example of a configuration of a vacuum processing system.

FIG. 3 is a vertical cross-sectional view illustrating an example of a configuration of a plasma processing apparatus according to the present embodiment.

FIG. 4 is a flowchart illustrating main steps of wafer processing according to the present embodiment.

FIG. 5 is a graph illustrating a relationship between a Vpp value during plasma non-ignition and input power.

FIG. 6 is a graph illustrating a relationship between transition power for generating inductively coupled plasma and input power.

FIG. 7 is a graph illustrating an example of a temporal change in a Vpp value during plasma processing according to the present embodiment.

FIG. 8 is a graph illustrating an example of a temporal change in a Vpp value during plasma processing according to the present embodiment.

FIG. 9 is a graph illustrating an example of a temporal change in the Vpp value during plasma processing according to the present embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In a manufacturing process of semiconductor devices and the like, plasma processing such as etching is performed on a semiconductor substrate (hereinafter simply referred to as “substrate”) using plasma. As an example, in the plasma processing, inductively coupled plasma (ICP) is generated in a processing container accommodating a substrate as a processing target, by supplying a radio frequency (RF) signal to a coil located above the processing container.

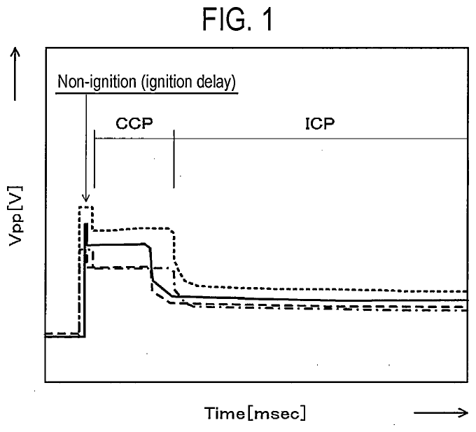

In the plasma processing, in order to suppress generation of abnormal discharges in an RF circuit, interlock control is performed to stop the supply of the RF signal when detecting a Volt peak to peak (Vpp) that is equal to or greater than a predetermined threshold value. However, due to influence of increase in power and the like in recent processes, there is concern that when ignition delay of plasma occurs (see FIG. 1), the Vpp exceeds the threshold value and abnormal discharges are generated in the RF circuit.

Further, it is known that when generating ICP in the processing container, capacitively coupled plasma (CCP) may transition to generate ICP in the processing container. However, transition of a plasma mode from CCP to ICP may require a large current, and there is concern that abnormal discharges are generated even during the transition of the plasma mode.

Furthermore, it is known that a resistance value of CCP is relatively large than that of ICP. Therefore, even when a low-power RF signal, which is used when performing plasma processing under generation of ICP, is supplied to the coil, there is concern that a large current may flow in the RF circuit under generation of CCP before the transition of the plasma mode (see FIG. 1). From this point of view, there is also concern that abnormal discharges may be generated.

Both of Patent Documents 1 and 2 described above disclose occurrence of ignition delay during plasma processing and transition of a plasma mode from CCP to ICP, but neither of them discloses or suggests generation of abnormal discharges due to the occurrence of the ignition delay or the transition of the plasma mode.

The technique of the present disclosure is made in view of the above-described circumstances, and appropriately suppresses generation of abnormal discharges in an RF circuit during plasma processing. Hereinafter, a plasma processing method and a plasma processing apparatus for performing the plasma processing method according to the present embodiments will be described with reference to the drawings. In addition, in this specification and the accompanying drawings, elements having substantially the same functional configuration will be denoted by the same reference numerals, and redundant descriptions thereof will be omitted.

### <Vacuum Processing System>

First, a configuration of a vacuum processing system according to an embodiment will be described.

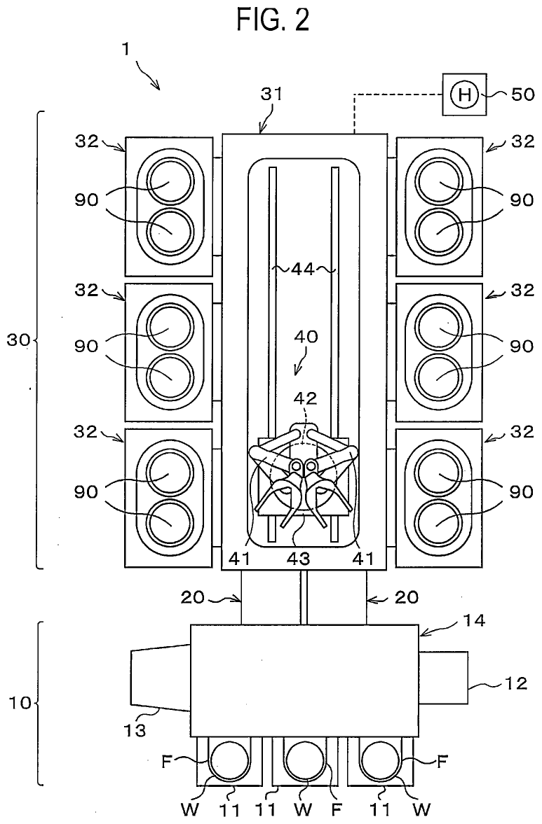

As illustrated in FIG. 2, a vacuum processing system 1 has a configuration in which an atmospheric part 10 and a depressurized part 30 are connected integrally via load lock modules 20.

The atmospheric part 10 includes a load port 11 on which front opening unified pods (FOUPs) F capable of storing a plurality of substrates W is placed, a cooling storage 12 configured to cool the substrates W after processed in the depressurized part 30, an aligner module 13 configured to adjust a horizontal orientation of the substrates W, and a loader module 14 configured to transfer the substrates W in the atmospheric part 10.

An interior of the loader module 14 is formed of a rectangular housing, and an interior of the housing is maintained to be atmospheric atmosphere. A plurality of, for example, three load ports 11 are provided in parallel on one side surface of the loader module 14 constituting long sides of the housing. A plurality of, for example, two load lock modules 20 are provided in parallel on the other side surface of the loader module 14 constituting the long sides of the housing. The cooling storage 12 is provided on one side surface of the loader module 14 constituting short sides of the housing. The aligner module 13 is provided on the other side surface of the loader module 14 constituting the short sides of the housing.

In addition, a wafer transfer mechanism (not illustrated) configured to transfer the substrates W is provided inside the loader module 14. The wafer transfer mechanism includes a transfer arm (not illustrated) that holds and moves the substrates W, and is configured to be capable of transferring the substrates W with respect to each of the FOUP F placed on the load port 11, the cooling storage 12, the aligner module 13, and the load lock modules 20.

Each load lock module 20 temporarily holds the substrates W transferred from the loader module 14 of the atmospheric part 10, in order to deliver the substrates W to a transfer module 31 of the depressurized part 30, which will be described later. The load lock module 20 includes a plurality of, for example, two stockers (not illustrated), thereby simultaneously holding two substrates W. Further, each load lock module 20 includes a gate valve (not illustrated) configured to ensure airtightness with respect to each of the loader module 14 and the transfer module 31 to be described later. By the gate valve, both airtightness and mutual communication between the loader module 14 and the transfer module 31 are compatible. Furthermore, a gas introducer (not illustrated) and a gas discharger (not illustrated) are connected to each load lock module 20, so that the interior of each load lock module 20 can be switched between atmospheric atmosphere and a depressurized atmosphere. In other words, the load lock module 20 is configured so that the substrates W can be delivered appropriately between the atmospheric part 10 under atmospheric pressure atmosphere and the depressurized part 30 under the depressurized atmosphere.

The depressurized part 30 includes the transfer module 31 that transfers two substrates W simultaneously, and plasma processing apparatuses 32 that perform desired plasma processing on the substrates W loaded from the transfer module 31. An interior of the transfer module 31 and interiors of the plasma processing apparatuses 32 are maintained to be depressurized atmospheres, respectively. In addition, a plurality of, for example, six plasma processing apparatuses 32 are provided with respect to the transfer module 31.

The interior of the transfer module 31 is formed of a rectangular housing and is connected to each load lock module 20 via the gate valve as described above. The transfer module 31 transfers the substrates W, which are loaded into the load lock module 20, to one or more plasma processing apparatuses 32 to perform the plasma processing, and then unloads the substrates W to the atmospheric part 10 via the load lock module 20.

A wafer transfer mechanism 40 configured to transfer the substrates W is provided in the transfer module 31. The wafer transfer mechanism 40 includes transfer arms 41 configured to hold and move two substrates W in a vertical arrangement, a rotary table 42 configured to rotatably support the transfer arms 41, and a rotary stage 43 on which the rotary table 42 is placed. In addition, a guide rail 44 extending in a longitudinal direction of the transfer module 31 is provided in the transfer module 31. The rotary stage 43 is provided on the guide rail 44 so that the wafer transfer mechanism 40 can move along the guide rail 44.

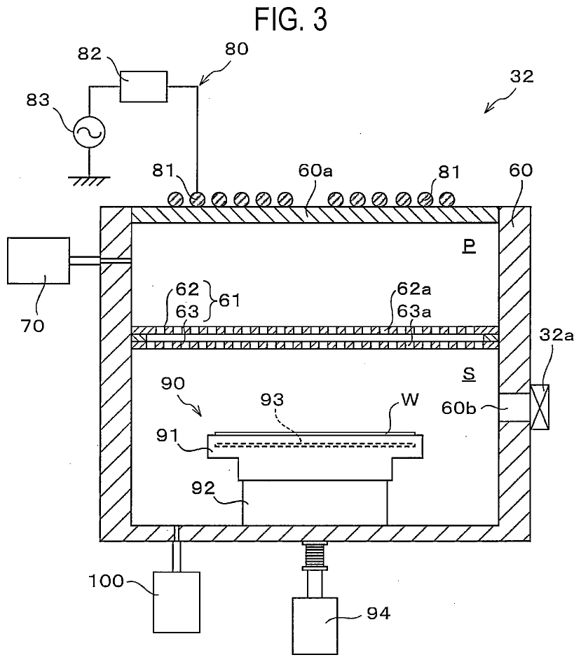

Each plasma processing apparatus 32 includes a gate valve 32a (see FIG. 3) for ensuring airtightness with respect to the transfer module 31. By the gate valve 32a, both airtightness and mutual communication between the transfer module 31 and the plasma processing apparatus 32 are compatible.

In addition, two stages 90, on which two substrates W are arranged horizontally and placed, are provided in the plasma processing apparatus 32. By arranging and placing the substrates W on the stages 90, the plasma processing apparatus 32 performs arbitrary plasma processing on two substrates W simultaneously. A detailed configuration of the plasma processing apparatus 32 will be described later.

A control device 50 is provided in the vacuum processing system 1 described above. The control device 50 is, for example, a computer having a CPU, a memory, and the like, and includes a program storage (not illustrated). The program storage stores a program for controlling processing for the substrate W in the vacuum processing system 1. In addition, the program storage also stores a program for controlling operations of a drive system such as various processing modules and transfer mechanisms described above to control wafer transfer timings in the vacuum processing system 1, which will be described later. In addition, the programs are recorded on a computer-readable storage medium H and may be installed from the storage medium H to the control device 50. In addition, the storage medium H may be transitory or non-transitory.

### <Plasma Processing Apparatus>

Next, details of a configuration of the plasma processing apparatus 32 will be described. FIG. 3 is a vertical cross sectional view schematically illustrating a configuration of the plasma processing apparatus 32. In addition, although two stages 90 are arranged horizontally in the plasma processing apparatus 32 as illustrated in FIG. 2, in FIG. 3, only one stage 90 is illustrated to avoid illustration complexity. In other words, FIG. 3 illustrates a vertical cross sectional view of the plasma processing apparatus 32 as viewed from one side constituting the short sides of the plasma processing apparatus 32.

As illustrated in FIG. 3, the plasma processing apparatus 32 includes a hermetically sealed processing container 60 configured to accommodate the substrate W. The processing container 60 is made of, for example, aluminum or an aluminum alloy, and has a, open top. The top of the processing container 60 is closed by a lid 60a that serves as a ceiling. A loading/unloading port 60b for the substrate W is provided on a side surface of the processing container 60. The loading/unloading port 60b is configured to be capable of being opened and closed by the gate valve 32a described above.

An interior of the processing container 60 is partitioned into an upper plasma generation space P and a lower processing space S by a partition 61. The plasma generation space P is a space where plasma is generated, and the processing space S is a space where the substrate W is subjected to plasma processing.

The partition 61 includes at least two plate-shaped members 62 and 63, which are disposed to overlap each other with a gap therebetween in a direction from the plasma generation space P toward the processing space S. The plate-shaped members 62 and 63 have slits 62a and 63a, which pass through the plate-shaped members 62 and 63 in the overlapping direction, respectively. The slits 62a and 63a are disposed not to overlap each other in a plan view. Thus, the partition 61 functions as a so-called ion trap that suppresses, when plasma is generated in the plasma generation space P, ions in the plasma from being transmitted to the processing space S. More specifically, by a labyrinth structure in which the slits 62a and 63a are arranged not to overlap each other, movement of ions that move anisotropically is blocked whereas radicals that move isotropically are transmitted.

The plasma generation space P includes a gas supply 70 configured to supply a processing gas into the processing container 60 and a plasma generator 80 configured to plasmarize the processing gas supplied into the processing container 60.

A plurality of gas sources (not illustrated) is connected to the gas supply 70 to supply a desired processing gas according to a purpose of plasma processing for the substrate W into the processing container 60. The processing gas supplied to the processing container 60 may be, for example, an oxygen-containing gas such as O₂ gas or a gas mixture containing a diluent gas such as Ar gas.

In addition, a flow rate regulator (not illustrated) configured to regulate an amount of the processing gas supplied to the plasma generation space P is provided in the gas supply 70. The flow rate regulator includes, for example, an on-off valve and a mass flow controller.

The plasma generator 80 is configured as an inductively coupled device using an RF antenna. The lid 60a of the processing container 60 is made of, for example, a quartz plate, and is configured as a dielectric window. RF antennas 81 are formed above the lid 60a to generate inductively coupled plasma in the plasma generation space P of the processing container 60. The RF antennas 81 are connected to a radio frequency power supply 83, which outputs an arbitrary output value of radio frequency power having a constant frequency appropriate for plasma generation (e.g., 13.56 MHz), via a matcher 82 having a matching circuit for impedance matching between a power supply side and a load side. In addition, two RF antennas 81 are provided correspondingly to the two stages 90 disposed in the processing space S, which will be described later.

The two stages 90 (only one of which is illustrated in FIG. 3 as described above), each placing one substrate W thereon horizontally, are disposed in the processing space S. Each stage 90 has a substantially cylindrical shape, and includes an upper stage 91 configured to place the substrate W thereon, and a lower stage 92 configured to support the upper stage 91. A temperature regulator 93 configured to regulate a temperature of the substrate W is provided inside the upper stage 91 regulate the temperature of the substrate W. Further, the stage 90 moves vertically by a lifting mechanism 94. The lifting mechanism 94 is disposed outside the processing container 60, and includes an actuator and the like configured to integrally move the two stages 90 vertically. Further, a plurality of lifting pins (not illustrated), which is used when loading and unloading the substrate W with respect to the processing container 60, is provided to be capable of protruding and retracting with respect to an upper surface of the upper stage 91.

An exhauster 100 is provided below the processing container 60. The exhauster 100 is connected to an exhaust mechanism (not illustrated) such as, for example, a vacuum pump via an exhaust pipe connected to the processing space S. Further, an automatic pressure control valve (APC) is provided in the exhaust pipe. An internal pressure of the processing container 60 is controlled by the exhaust mechanism and the automatic pressure control valve.

In addition, operations of the plasma processing apparatus 32 described above can be controlled by the aforementioned control device 50. In other words, the control device 50 may store a program for controlling the processing for the substrate W in the plasma processing apparatus 32. However, a control device for controlling operations of the plasma processing apparatus 32 is not necessarily the control device 50 provided outside the plasma processing apparatus 32. For example, operations of the plasma processing apparatus 32 may be controlled using a controller (not illustrated) provided independently in the plasma processing apparatus 32.

### <Plasma Processing Method>

The vacuum processing system 1 and the plasma processing apparatus 32 according to the present embodiment are configured as described above. Next, plasma processing for the substrate W performed using the plasma processing apparatus 32 will be described.

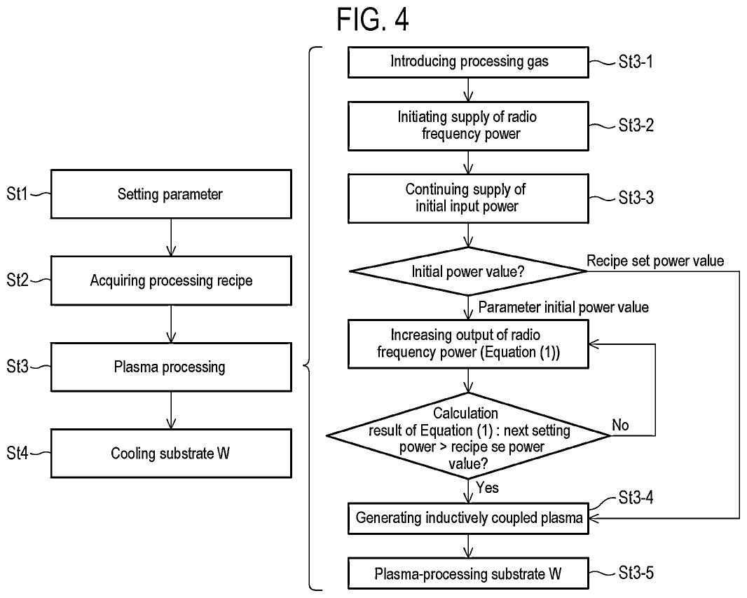

When plasma processing is performed on the substrate W, first, parameters relating to the plasma processing are acquired and set (step St1 in FIG. 4). The parameters set in step St1 may be input by an operator when performing the plasma processing on the substrate W, or may be output to the control device 50 in advance.

The parameters set in step St1 include, for example, an initial power application time for the plasma processing apparatus 32, an interlock value of Vpp for the plasma processing apparatus 32, an initial input value of radio frequency power supplied to the RF antenna 81 in the plasma processing (hereinafter referred to as “parameter initial power value”), and an output suppress ratio to be described later.

The initial power application time is a time during which radio frequency power of an initial setting value is applied to the RF antenna 81. A ignition delay time (see “ignition delay” in FIG. 1) refers to a time after the radio frequency power is applied to the RF antenna 81 until plasma is actually generated (ignited) in the plasma generation space P.

The interlock value of Vpp (hereinafter referred to as “VppI/L setting value”) is a setting value (Vpp value) when supply of RF signals is stopped by interlock control as described above, and serves as a threshold value for suppressing generation of abnormal discharges during the plasma processing.

The parameter initial power value as a first initial power value is determined based on, for example, the relationship between an input power to the RF antenna 81 and a Vpp value during plasma non-ignition (during an ignition delay time), which is illustrated in FIG. 5, and the aforementioned VppI/L setting value. In other words, after a start of supplying radio frequency power to the RF antenna 81 and before generation of inductively coupled plasma, the plasma processing apparatus 32 sequentially transitions from a state in which plasma is not ignited to a state in which capacitively coupled plasma is generated. In addition, since the Vpp value until the inductively coupled plasma is generated becomes largest in the plasma non-ignition state as illustrated in FIG. 1, in order to prevent activation of the interlock function or generation of abnormal discharges at least during the plasma non-ignition state, the parameter initial power value of the radio frequency power supplied to the RF antenna 81 is determined to be a value less than the VppI/L setting value.

Specifically, for example, when the VppI/L setting value (threshold value) is 3,500 V, referring to FIG. 5, since the Vpp value reaches 3,500 V at the input power of approximately 550 W, the parameter initial power value is set to be less than 550 W.

Once the parameters relating to the plasma processing are acquired and set, subsequently, a processing recipe for the plasma processing to be performed on the substrate W in the plasma processing apparatus 32 is acquired (step St2 in FIG. 4). The processing recipe for the plasma processing is assigned to each of a plurality of substrates W to be processed in the plasma processing apparatus 32.

The processing recipe acquired in step St2 includes, for example, a type of the plasma processing to be performed on the substrate W, a setting value of the radio frequency power supplied to the RF antenna 81 during the plasma processing (hereinafter referred to as a “recipe set power value”), a processing time, and a control cycle to be described later.

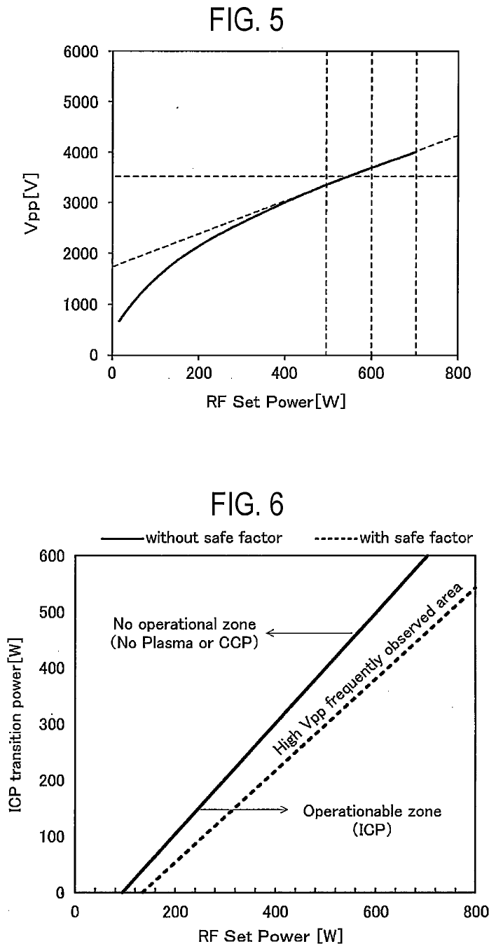

The recipe set power value as a second initial power value is an input value of the radio frequency power supplied to the RF antenna 81 when actually performing the plasma processing on the substrate W, and is set to be a value at least equal to or greater than the transition power illustrated in FIG. 6. In other words, the recipe set power value is set to be a value capable of generating inductively coupled plasma for performing the plasma processing on the substrate W.

In the plasma processing apparatus 32, by supplying the radio frequency power to the RF antenna 81 as described above, inductively coupled plasma is generated in the plasma generation space P to perform processing on the substrate W. However, when the radio frequency power supplied to the RF antenna 81 is less than the transition power, plasma cannot be generated in the plasma generation space P, or capacitively coupled plasma cannot transition to inductively coupled plasma. Thus, there is concern that plasma processing on the substrate W may not be performed. In addition, in a (non-ignition) state where plasma is not generated in the plasma generation space P or in a state where capacitively coupled plasma is generated, as illustrated in FIG. 1, a large current may flow in the RF circuit compared to a state where inductively coupled plasma is generated, that is, risk of generation of abnormal discharges increases.

Therefore, during the plasma processing for the substrate W, the recipe set power value of the radio frequency power supplied to the RF antenna 81 is set to be equal to or greater than the transition power illustrated in FIG. 6, whereby inductively coupled plasma is appropriately generated by supplying radio frequency power of the recipe set power value to the RF antenna 81 to perform the plasma processing on the substrate W appropriately.

In addition, the recipe set power value is set such that a Vpp value measured by supplying the radio frequency power of the recipe set power value becomes smaller than at least the aforementioned VppI/L setting value.

Specifically, for example, when the VppI/L setting value (threshold value) is 3,500 V, referring to FIG. 5, since the Vpp value reaches 3,500 V at the input power of approximately 550 W, the recipe set power value is set to be a value that is equal to or greater than the transition power and smaller than 550 W (on the right-hand side of the thick line and the left-hand side of the one-dot dashed line in FIG. 6).

When the processing recipe for the plasma processing is acquired, subsequently, the plasma processing for the substrate W in the plasma processing apparatus 32 (step St3 in FIG. 4) is started.

In the plasma processing for the substrate W, first, the substrate W as a processing target is placed on the stage 90 in the processing space S. The substrate W as the processing target is taken out from the FOUP F placed on the load port 11 by the wafer transfer mechanism (not illustrated), the horizontal orientation of the substrate W is adjusted in the aligner module 13, and then the substrate W is loaded into the plasma processing apparatus 32 via the load lock module 20 and the wafer transfer mechanism 40 and placed on the stage 90.

In addition, as described above, the processing recipe for the plasma processing to be performed in the plasma processing apparatus 32 is assigned to the substrate W as the processing target.

When the substrate W is placed on the stage 90, subsequently, the processing gas is supplied from the gas supply 70 to the plasma generation space P (step St3-1 in FIG. 4), and the radio frequency power is supplied to the RF antenna 81 to initiate plasma generation in the plasma generation space P.

Here, in the plasma processing for the substrate W, as described above, until the inductively coupled plasma (ICP) used for the plasma processing is generated, sequential transition from the plasma non-ignition state to the capacitively coupled plasma (CCP) generation state is performed. At this time, during the plasma non-ignition state and the capacitively coupled plasma generation state, as illustrated in FIG. 1, it is likely that a larger current flows in the RF circuit compared to when inductively coupled plasma is generated. Thus, the risk of generation of abnormal discharges due to the supply of the radio frequency power is high.

Therefore, in the plasma processing according to the present embodiment, the radio frequency power (initial input value) supplied to the RF antenna 81 at the initiation of plasma generation is determined to be a lower power value between the parameter initial power value set in step St1 and the recipe set power value acquired in step St2. In other words, along with the supply of the processing gas to the plasma generation space P in step St3-1, low power, which is selected from the parameter initial power value and the recipe set power value, is supplied to the RF antenna 81 as the initial input power (step St3-2 in FIG. 4).

As described above, the parameter initial power value set in step St1 is set to be lower than the VppI/L setting value to prevent activation of the interlock function or generation of abnormal discharges. Therefore, in step St3-2, generation of abnormal discharges during the plasma non-ignition state is suppressed by supplying radio frequency power lower than at least the parameter initial power value.

Further, by selecting, as the initial input power, a lower value between the parameter initial power value and the recipe set power value, for example, even when the operator incorrectly inputs the recipe set power value, it is suppressed that a large current flows in the RF circuit based on the incorrect recipe input, and it is possible to start the plasma processing based on the parameter initial power value that prevents activation of the interlock function or generation of abnormal discharges.

Further, during the plasma processing according to the present embodiment, the radio frequency power of the initial input power value (the parameter initial power value or the recipe set power value) determined in step St3-2 is continuously supplied for at least a time duration equal to or greater than the ignition delay time set in step St1 (step St3-3 in FIG. 4).

As will be described later, in the plasma processing according to the present embodiment, when the parameter initial power value is set as the initial power value in step St3-2, an output of the radio frequency power supplied to the RF antenna 81 is increased stepwise from the initial power value to the recipe set power value. At this time, when the output of the radio frequency power is increased (increase in power) during the plasma non-ignition state, a large current may flow in the RF circuit, resulting in activation of the interlock function or generation of abnormal discharges.

Therefore, in the present embodiment, the initial power value of the radio frequency power is maintained during a time duration equal to or greater than the initial power application time set in step St1, more specifically, at least until plasma is generated in the plasma generation space P. Thus, it is possible to suppress generation of abnormal discharges during the plasma non-ignition state.

In addition, whether or not capacitively coupled plasma is generated in the plasma generation space P can be determined by, for example, measuring the Vpp value or a current value of the radio frequency power supplied to the RF antenna 81 over time. As illustrated in FIG. 1, the Vpp value measured during the plasma non-ignition state is higher than the Vpp value measured when the capacitively coupled plasma is generated. The reason is because when capacitively coupled plasma is generated in the plasma generation space P, a resistance is generated in the plasma, and the radio frequency power supplied to the RF antenna 81 is consumed by the resistance. Therefore, in the plasma processing according to the present embodiment, when a change in the measured Vpp value is detected, it may be determined that the plasma generation space P has transitioned from the plasma non-ignition state to the capacitively coupled plasma generation state.

In addition, in the plasma processing according to the present embodiment, whether or not plasma is generated may be determined based on the temporal change in the Vpp value (current value) in addition to a lapse of the initial power application time, and the procedure may proceed to a subsequent plasma processing step at a timing when the risk of generation of abnormal discharges is reduced.

When the initial power value has been continuously supplied for a time duration equal to or greater than the initial power application time and the capacitively coupled plasma is generated in the plasma generation space P, subsequently, inductively coupled plasma is generated in the plasma generation space P (step St3-4 in FIG. 4). In other words, the capacitively coupled plasma generated in the plasma generation space P transitions to the inductively coupled plasma.

Here, in step St3-2, when the recipe set power value is selected as the initial input power supplied to the RF antenna 81, i.e., when the recipe set power value is less than the parameter initial power value, the radio frequency power of the recipe set power value is continuously supplied to the RF antenna 81.

As described above, since the recipe set power value is set to be equal to or greater than the transition power illustrated in FIG. 6, by continuously supplying the radio frequency power of the recipe set power value, a density of the capacitively coupled plasma in the plasma generation space P is increased, resulting in generation of the inductively coupled plasma (step St3-4).

In addition, as described above, since the recipe set power value is set to be less than the VppI/L setting value set in step St1, generation of abnormal discharges is suppressed during the supply of the radio frequency power of the recipe set power value.

On the other hand, when the parameter initial power value is selected as the initial input power supplied to the RF antenna 81 in step St3-2, i.e., when the parameter initial power value is less than the recipe set power value, the output of the radio frequency power supplied to the RF antenna 81 is increased stepwise from the parameter initial power value to the recipe set power value. In other words, the parameter initial power value, which is the initial input power, is increased stepwise to a value capable of generating the inductively coupled plasma for performing the plasma processing on the substrate W.

Specifically, based on the following Equation (1), the output of the radio frequency power supplied to the RF antenna 81 is increased for each control cycle set in step St1. In addition, the control cycle is set to be 100 msec in an example, but a value of the control cycle is not limited thereto and may be set arbitrarily:

$$Next Setting Power = Current Setting power \times Output Suppress Ratio \times VppI / L Setting Value / Current Vpp Value \qquad ( 1 )$$

where “Next Setting Power” is an output [W] of the radio frequency power supplied to the RF antenna 81 in the next control cycle, “Current Setting Power” is an output [W] of the radio frequency power supplied to the RF antenna 81 in the current control cycle, “Output Suppress Ratio” is a coefficient (<1.0) that determines an amount of change in power up to the recipe set power value as the setting power, “VppI/L Setting Value” is an interlock value of Vpp in the plasma processing apparatus 32, and “Current Vpp Value” is a Vpp value measured during the supply of the radio frequency power of the current setting power.

In addition, as described above, the output suppress ratio in Equation (1) is a coefficient that determines an amount of change in power up to the recipe set power value, i.e., a coefficient that determines a difference between the next setting power and the current setting power. The output suppress ratio may be set to be a value of 0.8 or more and 0.95 or less, more specifically, 0.9. When the output suppress ratio exceeds 0.95, there is a risk of overshooting according to a monitor value of Vpp. Further, in particular, when the output suppress ratio is set to be 1.0, there is concern that the monitor value of Vpp may exceed the VppI/L setting value to activate the activation of the interlock function. On the other hand, when the output suppress ratio is less than 0.8, an increase in the radio frequency power supplied to the RF antenna 81 becomes slower, and there is concern that process results of the plasma processing for the substrate W may vary.

In the plasma processing according to the present embodiment, the increase in power of the radio frequency power based on Equation (1) is repeated, while feeding back the power of the radio frequency power according to the current Vpp value, until a setting power of the radio frequency power reaches the recipe set power value and the inductively coupled plasma is generated in the plasma generation space P. At this time, since the recipe set power value is set to be equal to or greater than the transition power as described above, when the setting power reaches the recipe set power value, it is possible to cause the capacitively coupled plasma in the plasma generation space P to transition to generate the inductively coupled plasma.

In addition, whether or not the inductively coupled plasma has been generated in the plasma generation space P may be determined based on, for example, the difference between the next setting power and the current setting power in Equation (1). Specifically, when inductively coupled plasma has not been generated in the plasma generation space P, since the current Vpp value in Equation (1) increases stepwise, the difference between the next setting power and the current setting power decreases stepwise. On the other hand, when inductively coupled plasma has been generated in the plasma generation space P, since inductively coupled plasma has a resistance value lower than capacitively coupled plasma, the current Vpp value in Equation (1) decreases as illustrated in FIG. 1, and as a result, the next setting power increases significantly compared to the current setting power.

Therefore, in the plasma processing according to the present embodiment, based on the difference between the next setting power and the current setting power, which is caused by a change in the measured Vpp value, it may be determined whether or not the capacitively coupled plasma has transitioned to the inductively coupled plasma in the plasma generation space P, and the procedure may proceed to a subsequent plasma processing step at a timing when the risk of generation of abnormal discharges is reduced.

After the inductively coupled plasma is generated in the plasma generation space P, the plasma processing for the substrate W is performed according to the processing recipe acquired in step St2 (step St3-5 in FIG. 4).

At this time, the inductively coupled plasma has been already generated in the plasma generation space P in step St3-4. Since the resistance value of inductively coupled plasma is lower than that of capacitively coupled plasma as described above, even when high power (e.g., 600 W or more) is supplied during the plasma processing for the substrate W, the current flowing in the RF circuit may be small, whereby the risk of generation of abnormal discharges is reduced.

During the plasma processing for the substrate W, the plasma generated in the plasma generation space P is supplied to the processing space S via the partition 61. Here, since the labyrinth structure is formed in the partition 61 as described above, only radicals generated in the plasma generation space P are transmitted to the processing space S. Then, by causing the radicals supplied to the processing space S to act on the substrate W placed on the stage 90, it is possible to perform the plasma processing on the substrate W.

Thereafter, when desired processing results are obtained for the substrate W, the plasma processing in the plasma processing apparatus 32 is terminated. When terminating the plasma processing, the supply of the radio frequency power to the RF antenna 81 and the supply of the processing gas from the gas supply 70 are stopped. In addition, the processing gas remaining in the processing space S is exhausted by operating the exhauster 100.

Subsequently, the substrate W having been subjected to the plasma processing is delivered from the stage 90 to the wafer transfer mechanism 40, and is unloaded from the processing container 60. The substrate W unloaded from the processing container 60 is transferred to the load lock module 20 by the wafer transfer mechanism 40. Thereafter, the substrate W undergoes cooling in the cooling storage 12 (step St4 in FIG. 4) and is then accommodated in the FOUP F placed on the load port 11. Then, when the desired plasma processing for all the substrates W accommodated in the FOUP F is terminated and the final substrate W is accommodated in the FOUP F, a series of wafer processing in the vacuum processing system 1 is terminated.

### <Operative Effects of Technique of Present Disclosure>

As described above, according to the plasma processing method of the present embodiment, in order to continuously operate the plasma processing apparatus 32 without generating abnormal discharges during the plasma processing for the substrate W, control is performed to increase the radio frequency power stepwise to the recipe set power value acquired in advance, while feeding back the setting power of the radio frequency power according to the measured Vpp value. Thus, since the Vpp value is suppressed from rapidly increasing to a specified value during the plasma processing, it is possible to suppress generation of abnormal discharges.

In addition, according to the present embodiment, the initial setting value of the radio frequency power supplied to the RF antenna 81 during the plasma processing is set to be a lower value between the parameter initial power value and the recipe set power value. In the present embodiment, since the parameter initial power value is set such that the Vpp value measured during the supply of the parameter initial power value is less than the VppI/L setting value, which is a threshold value that activates the interlock function, it is possible to more appropriately suppress generation of abnormal discharges particularly before plasma is generated in the plasma generation space P (during the ignition delay time).

In addition, according to the present embodiment, the Vpp value is measured over time during the generation of capacitively coupled plasma and the generation of inductively coupled plasma in the plasma generation space P. Thus, it is possible to easily detect a transition timing from the plasma non-ignition state to the capacitively coupled plasma generation state and a transition timing of a plasma mode from the capacitively coupled plasma to the inductively coupled plasma in the plasma generation space P. Therefore, since a switching timing of control relating to the plasma processing can be recognized appropriately it is possible to appropriately reduce throughput relating to the plasma processing.

In addition, according to the present embodiment, the output suppress ratio in Equation (1) is set to be a value of 0.8 or more and 0.95 or less. Thus, it is possible to cause the setting power to reach the recipe set power value as quickly as possible while suppressing generation of abnormal discharges during the plasma generation in the plasma generation space P. In other words, it is possible to reduce a time required to generate inductively coupled plasma in the plasma generation space P while suppressing generation of abnormal discharges.

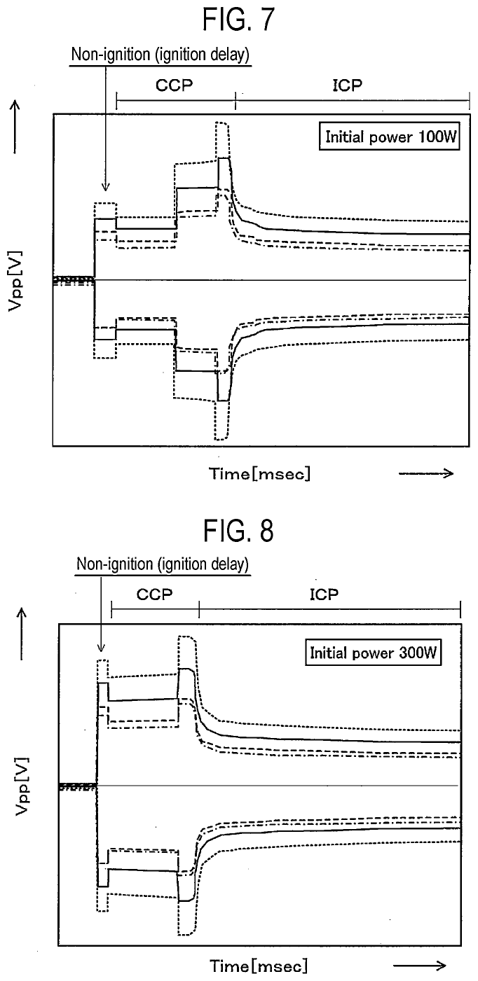

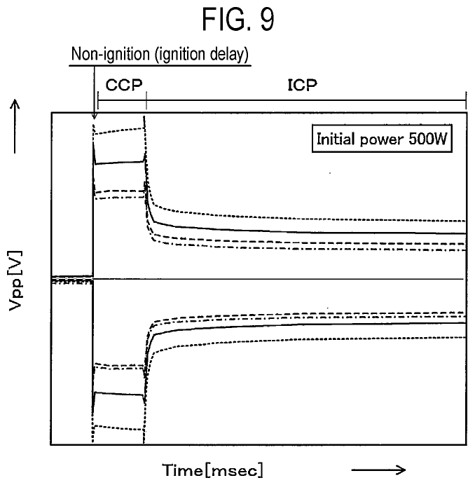

FIGS. 7 to 9 illustrate examples of the plasma processing according to the technique of the present disclosure, and are graphs showing temporal changes in the Vpp value when setting the parameter initial power value of the radio frequency power supplied to the RF antenna 81 to be 100 W (FIG. 7), 300 W (FIG. 8), and 500 W (FIG. 9), while the recipe set power value, the initial power application time, and the output suppress ratio are commonly set to be 700 W, 0.2 msec, and 0.9, respectively. In other words, in any case illustrated in FIGS. 7 to 9, the initial input power is set to be the parameter initial power value.

As illustrated in FIGS. 7 to 9, it can be recognized that according to the plasma processing of the technique of the present disclosure, abnormality i.e., generation of abnormal discharges or activation of the interlock control, does not occur in the Vpp value until the inductively coupled plasma (ICP) is generated in the plasma generation space P as described above.

According to the present disclosure, it is possible to appropriately suppress generation of abnormal discharges in an RF circuit during plasma processing.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing method using a plasma processing apparatus, comprising:
acquiring a parameter including a first initial power value, an initial power application time, and an output suppress ratio;
acquiring a processing recipe including a recipe set power value as a second initial power value; and
determining initial input power to an antenna for plasma excitation from either the first initial power value or the second initial power value,
wherein when the first initial power value is determined as the initial input power, the method further comprises:
supplying the determined initial input power to the antenna for plasma excitation for at least a time duration equal to or greater than the initial power application time; and
increasing an output of radio frequency power supplied to the antenna for plasma excitation stepwise from the initial input power to the recipe set power value.

2. The plasma processing method of claim 1, wherein the initial input power is set to be a lower power value between the first initial power value and the second initial power value.

3. The plasma processing method of claim 2, wherein the first initial power value is set such that a Vpp value measured after a start of supplying the first initial power value to the antenna for plasma excitation and before a lapse of the initial power application time is less than a threshold value that activates interlock function of the plasma processing apparatus.

4. The plasma processing method of claim 3, wherein the stepwise increase in the output of the radio frequency power supplied to the antenna for plasma excitation is performed for each control cycle based on the following Equation (1):
$$Next Output = Current Output \times Output Suppress Ratio \times VppI / L Setting Value / Current Vpp Value \qquad ( 1 )$$
where, Next Output” is an output of the radio frequency power supplied to the antenna for plasma excitation in a next control cycle,
“Current Output” is an output of the radio frequency power supplied to the antenna for plasma excitation in a current control cycle,
“Output Suppress Ratio” is a coefficient that determines an amount of change in output up to the recipe set power value,
“VppI/L Setting Value” is a threshold value that activates interlock function of the plasma processing apparatus, and
“Current Vpp Value” is a Vpp value measured during supplying a current output to the antenna for plasma excitation.

5. The plasma processing method of claim 4, wherein the output suppress ratio is set to be a value of 0.8 or more and 0.95 or less.

6. The plasma processing method of claim 1, further comprising when the second initial power value is determined as the initial input power, maintaining the output of the radio frequency power supplied to the antenna to be the recipe set power value until inductively coupled plasma (ICP) is generated.

7. The plasma processing method of claim 1, wherein the stepwise increase in the output of the radio frequency power supplied to the antenna for plasma excitation is performed for each control cycle based on the following Equation (1):
$$Next Output = Current Output \times Output Suppress Ratio \times VppI / L Setting Value / Current Vpp Value \qquad ( 1 )$$
where, Next Output” is an output of the radio frequency power supplied to the antenna for plasma excitation in a next control cycle,
“Current Output” is an output of the radio frequency power supplied to the antenna for plasma excitation in a current control cycle,
“Output Suppress Ratio” is a coefficient that determines an amount of change in output up to the recipe set power value,
“VppI/L Setting Value” is a threshold value that activates interlock function of the plasma processing apparatus, and
“Current Vpp Value” is a Vpp value measured during supplying a current output to the antenna for plasma excitation.

8. A plasma processing apparatus comprising:
a processing container;
a stage disposed inside the processing container and configured to place a substrate as a processing target on the stage;
an antenna for plasma excitation disposed above the processing container;
a radio frequency power supply configured to supply radio frequency power to the antenna for plasma excitation; and
a controller,
wherein the controller executes:
control to acquire a parameter including a first initial power value, an initial power application time, and an output suppress ratio;
control to acquire a processing recipe including a recipe set power value as a second initial power value; and
control to determine initial input power to the antenna for plasma excitation from any of the first initial power value and the second initial power value, and
wherein when the first initial power value is determined as the initial input power, the controller further executes:
control to supply the determined initial input power to the antenna for plasma excitation for at least a time duration equal to or greater than the initial power application time; and
control to increase an output of radio frequency power supplied to the antenna for plasma excitation stepwise from the initial input power to the recipe set power value.
